(19) United States
(12) Patent Application Publication
(10) Pub. No.: US 2023/0019579 A1
(43) Pub. Date: Jan. 19, 2023

(54) METHOD AND SYSTEM FOR CONTROLLING DEPOSITION DEVICE

(71) Applicant: CHANGXIN MEMORY TECHNOLOGIES, INC., Hefei City (CN)

(72) Inventor: Tao Liang, Hefei City (CN)

(21) Appl. No.: 17/453,207

(22) Filed: Nov. 2, 2021

Related U.S. Application Data
(63) Continuation of application No. PCT/CN2021/107773, filed on Jul. 22, 2021.

(30) Foreign Application Priority Data
Jul. 13, 2021 (CN) 202110790789.5

(51) Int. Cl. C23C 14/54; H01J 37/32; C23C 14/34; C23C 14/50; B08B 5/00; B08B 9/08

(52) U.S. Cl. CPC C23C 14/54; H01J 37/32862; H01J 37/32935; H01J 37/32807; C23C 14/34; C23C 14/50; B08B 5/00; B08B 9/08; H01L 21/6831

(57) ABSTRACT

The present disclosure provides a method and system for controlling a deposition device, relating to the field of semiconductor technology. The method for controlling a deposition device is applied to the deposition device, the deposition device includes a reaction chamber and an electrostatic chuck arranged in the reaction chamber, the electrostatic chuck carries a wafer, and the controlling method includes: obtaining a pressure value between the wafer and the electrostatic chuck; and when the pressure value exceeds a preset range, the deposition device sending out an alarm signal, and executing a cleaning operation according to a use state of the electrostatic chuck.

### CROSS-REFERENCE TO RELATED APPLICATIONS

This is a continuation of International Application No. PCT/CN2021/107773, filed on Jul. 22, 2021, which claims the priority to Chinese Patent Application 202110790789.5, titled “METHOD AND SYSTEM FOR CONTROLLING DEPOSITION DEVICE” and filed on Jul. 13, 2021. The entire contents of International Application No. PCT/CN2021/107773 and Chinese Patent Application 202110790789.5 are incorporated herein by reference.

### TECHNICAL FIELD

The present disclosure relates to, but is not limited to, a method and system for controlling a deposition device.

### BACKGROUND

In a semiconductor processing device, an Electrostatic Chuck (E-Chuck) for placing a wafer is usually located in a reaction chamber. The use state of the electrostatic chuck will affect the processing effect of the wafer.

For a deposition device, when there are contaminants on the surface of the electrostatic chuck, through holes on the surface of the electrostatic chuck will be blocked. As a result, the air flow is uneven, the electrostatic attraction capacity is reduced, eventually the back pressure of the wafer is abnormally alarmed, the state of the reaction chamber is abnormal, the manufacturing process is terminated, and the production capacity is reduced.

### SUMMARY

The subject matter is described in detail herein below, which is not intended to limit the scope of protection of claims.

The present disclosure provides a method and system for controlling a deposition device.

The first aspect of the present disclosure provides a method for controlling a deposition device, applied to the deposition device, the deposition device including a reaction chamber and an electrostatic chuck arranged in the reaction chamber, the electrostatic chuck carrying a wafer, the method for controlling the deposition device including:

obtaining a pressure value between the wafer and the electrostatic chuck; and

when the pressure value exceeds a preset range, the deposition device sending out an alarm signal, and executing a cleaning operation according to a use state of the electrostatic chuck.

According to some embodiments of the present disclosure, the executing the cleaning operation according to the use state of the electrostatic chuck includes:

determining whether a working state of the electrostatic chuck meets use requirements, wherein the working state is configured to characterize the use state of the electrostatic chuck; and

if the working state of the electrostatic chuck meets the use requirements, executing the cleaning operation.

The second aspect of the present disclosure provides a system for controlling a deposition device, applied to the deposition device, the deposition device including a reaction chamber and an electrostatic chuck arranged in the reaction chamber, the electrostatic chuck carrying a wafer, the system for controlling the deposition device including an obtaining module, a control module, an alarm module and an execution module, the control module is connected to the obtaining module, the alarm module, and the execution module respectively;

the obtaining module is configured to obtain a pressure value between the wafer and the electrostatic chuck;

the control module is configured to receive the pressure value, determine whether the pressure value exceeds a preset range, obtain a use state of the electrostatic chuck, and generate an operation instruction according to the determination result and the use state of the electrostatic chuck;

the alarm module is configured to be controlled by the control module to send out an alarm signal when the pressure value exceeds the preset range;

the execution module is configured to receive the operation instruction, and execute a cleaning operation according to the operation instruction.

After the drawings and detailed description are read and understood, other aspects may be understood.

### BRIEF DESCRIPTION OF THE DRAWINGS

The drawings, which are incorporated in and constitute a part of the specification, illustrate embodiments of the present disclosure and together with the description serve to explain the principles of the embodiments of the present disclosure. In these drawings, similar reference numerals are configured to represent similar elements. The drawings in the following description are only some rather than all of the embodiments of the present disclosure. For those of ordinary skill in the art, other drawings can be obtained based on these drawings without any creative efforts.

FIG. 1 is a process flowchart of a method for controlling a deposition device according to an exemplary embodiment;

FIG. 2 is a process flowchart of a method for controlling a deposition device according to an exemplary embodiment;

FIG. 3 is a process flowchart of a method for controlling a deposition device according to an exemplary embodiment;

FIG. 4 is an effect diagram after a second cleaning operation is executed in the method for controlling a deposition device according to an exemplary embodiment;

FIG. 5 is a schematic diagram of a reaction chamber in the method for controlling a deposition device according to an exemplary embodiment;

FIG. 6 is a schematic diagram of an electrostatic chuck in the method for controlling a deposition device according to an exemplary embodiment;

FIG. 7 is a schematic diagram of executing a first cleaning operation in the method for controlling a deposition device according to an exemplary embodiment;

FIG. 8 is a schematic diagram of executing a second cleaning operation in the method for controlling a deposition device according to an exemplary embodiment;

FIG. 9 is a schematic diagram of a system for controlling a deposition device according to an exemplary embodiment.

### DETAILED DESCRIPTION

In order to make the objectives, technical solutions and advantages of the embodiments of the present disclosure clearer, the following clearly and completely describes the technical solutions in the embodiments of the present disclosure with reference to the accompanying drawings in the embodiments of the present disclosure. Apparently, the described embodiments are only part of the embodiments of the present disclosure, not all of them. All other embodiments obtained by those skilled in the art based on the embodiments of the present disclosure without any creative efforts shall fall within the protection scope of the present disclosure. It should be noted that the embodiments in the present disclosure and the features in the embodiments can be combined with each other on a non-conflict basis.

In a semiconductor processing device, an Electrostatic Chuck (E-Chuck) for placing a wafer is usually arranged. The use state of the electrostatic chuck will affect the carrying effect of the wafer, and further affect the process effect.

The inventor found, in actual production, with regard to a deposition device, especially a high-temperature deposition device, an oxide is easily formed in its reaction chamber during heating, and adheres to the surface of the electrostatic chuck. The inventor also found, some substances on the back of the wafer fall to the surface of the electrostatic chuck due to high-temperature baking. As a result, through holes on the surface of the electrostatic chuck are blocked to reduce its conductivity, the air flow is uneven, the electrostatic attraction capacity is reduced, eventually an alarm is given for abnormal pressure on the back of the wafer, the state of the reaction chamber is abnormal, the manufacturing process is terminated, and the production capacity is reduced.

In view of the above technical problems, the method and system for controlling a deposition device provided by the embodiments of the present disclosure can perform a corresponding cleaning operation according to the use state of the electrostatic chuck when the back pressure of the wafer is abnormally alarmed, to effectively remove contaminants from the surface of the electrostatic chuck, thereby effectively solving the problem of abnormal alarm for the back pressure of the wafer, reducing the downtime of troubleshooting, ensuring the smooth progress of products, and increasing the production capacity of the device.

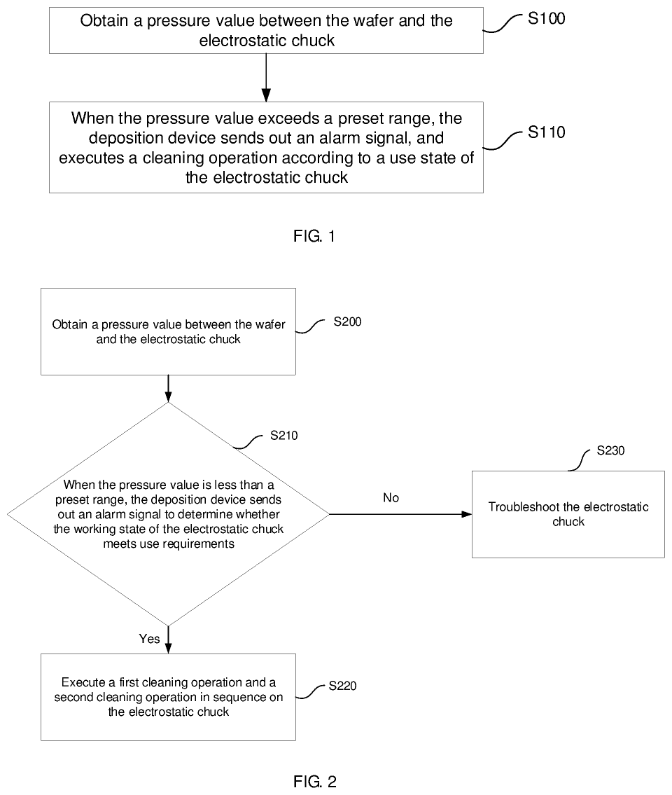

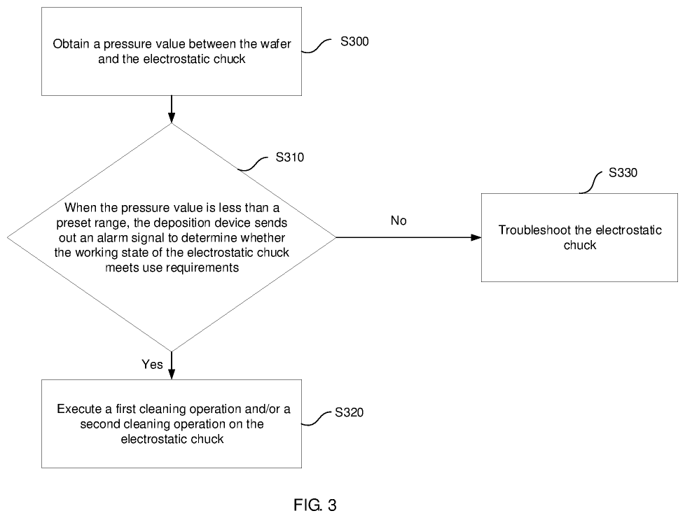

An exemplary embodiment of the present disclosure provides a method for controlling a deposition device, as shown in FIG. 1. FIG. 1 shows a flowchart of a method for controlling a deposition device according to an exemplary embodiment of the present disclosure, FIG. 2 shows a flowchart of a method for controlling a deposition device according to another exemplary embodiment of the present disclosure, and FIG. 3 shows a flowchart of a method for controlling a deposition device according to still another exemplary embodiment of the present disclosure. The method for controlling a deposition device will be introduced below in conjunction with the accompanying drawings.

This embodiment does not limit the deposition device. The following will take a high-temperature deposition device as an example for description, but this embodiment is not limited thereto, and the deposition device in this embodiment may also be other device.

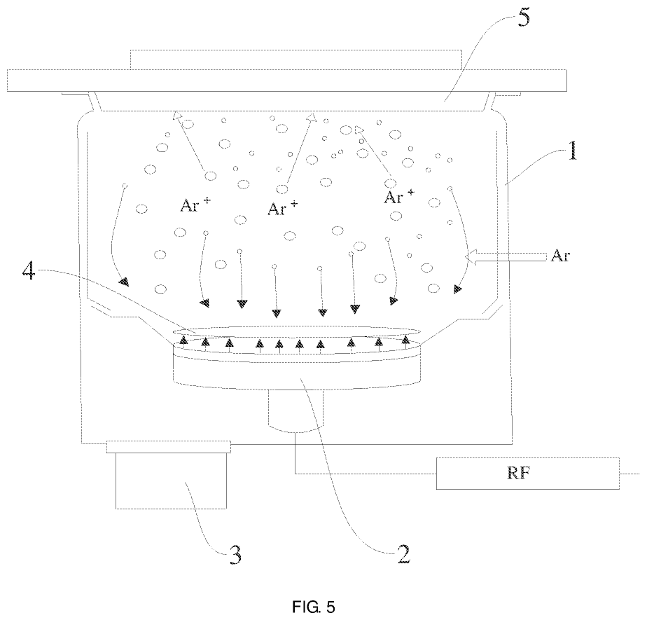

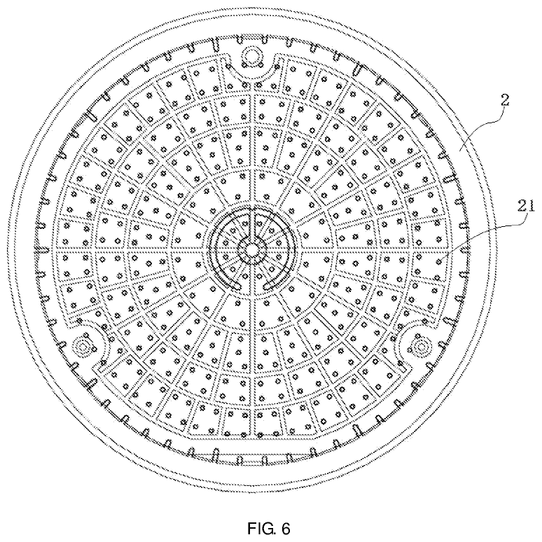

As shown in FIG. 1, an exemplary embodiment of the present disclosure provides a method for controlling a deposition device, which is applied to the deposition device. Referring to FIG. 5, the deposition device includes a reaction chamber 1 and an electrostatic chuck 2 arranged in the reaction chamber 1, the electrostatic chuck 2 carries a wafer 4, and the electrostatic chuck 2 may be provided with a plurality of through holes arranged uniformly, as shown in FIG. 6.

According to an embodiment of the present disclosure, the method for controlling a deposition device in the present disclosure includes the following steps:

Step S100: obtaining a pressure value between the wafer and the electrostatic chuck.

In this embodiment, referring to FIG. 5, the wafer 4 is attracted to the electrostatic chuck by electrostatic attraction. That is, a voltage is applied to an electrode of the electrostatic chuck 2, to produce an electrostatic attraction force between the electrode and the wafer 4, so that the wafer 4 is attracted and fixed on the electrostatic chuck 2.

Exemplarily, when the deposition device is processing the wafer 4, after the wafer 4 is fixed by electrostatic attraction and the back pressure of the wafer 4 is stable and reaches the range required by the construction process, the processing is performed, for example, deposition or etching is performed.

The back pressure value of the wafer 4 is a visual display of the attraction and fixation between the wafer 4 and the electrostatic chuck 2. It should be noted that the pressure value when the wafer is stable, that is, the pressure value between the wafer 4 and the electrostatic chuck 2, can be measured and read by a pressure gauge in the deposition device. When the pressure value is within the range required by the construction process of the wafer, displacement or slippage of the wafer during the processing can be avoided.

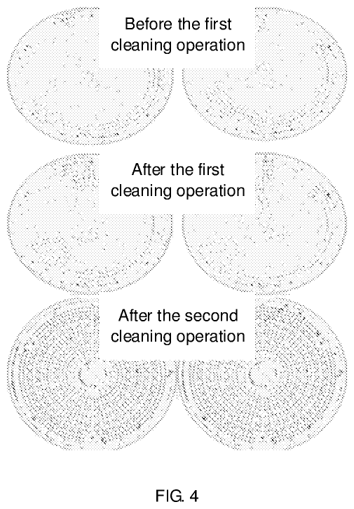

Alternatively, as shown in FIG. 4, the attraction effect between the wafer 4 and the electrostatic chuck 2 is characterized by an electrostatic chuck hole map. The attraction effect can also feed the pressure value of attraction between the wafer 4 and the electrostatic chuck 2 back. When the attraction effect between the electrostatic chuck 2 and the wafer 4 is good, the electrostatic chuck hole map shows corresponding attraction protrusions, and a pattern in accordance with the arrangement of the through holes on the electrostatic chuck is formed on the attraction protrusions. During the processing of the wafer, as the production capacity increases, the through holes will be blocked by the oxide in the reaction chamber. As such, when the wafer is attracted to the electrostatic chuck, attraction protrusions will not be formed at the blocked through holes on the electrostatic chuck hole map. That is, the electrostatic chuck hole map can be configured to characterize the use state of the electrostatic chuck.

Step S110: when the pressure value exceeds a preset range, the deposition device sending out an alarm signal, and executing a cleaning operation according to a use state of the electrostatic chuck.

Exemplarily, the preset range is a range of the back pressure value of the wafer that is required by the construction process for processing in the deposition device, for example, the preset range may be 4 Torr to 8 Torr. When the pressure value is less than 4 Torr or the pressure value is greater than 8 Torr, the deposition device sends out an alarm signal. The alarm signal may be accomplished by an alarm module or an alarm in the deposition device, for example, by a sound and light alarm, a buzzer, or a flashing indicator. The pressure value between the wafer and the electrostatic chuck exceeding the preset range includes the following two situations. The pressure value is less than the preset range, and the pressure value is greater than the preset range.

When the pressure value is less than the preset range, the deposition device sends out an alarm signal to warn the staff, and executes a corresponding cleaning operation on the electrostatic chuck according to the use state of the electrostatic chuck.

When the pressure value is greater than the preset range, the deposition device sends out an alarm signal to warn the staff to handle in time. In a disclosed embodiment, different alarm signals may be configured in the above two situations for the staff to distinguish and handle. For example, when the pressure value is less than the preset range, the buzzer or flashing indicator sends out a corresponding buzzer alarm signal or light alarm signal; when the pressure value is greater than the preset range, the sound and light alarm sends out a corresponding sound and light alarm signal.

It should be noted that when the pressure value is greater than the preset range, the electrode voltage between the wafer and the electrostatic chuck can be adjusted to adjust the pressure value between the two, so as to avoid the damage of the wafer due to excessive pressure value.

The controlling method of the above disclosed embodiment is implemented to clean the surface of the electrostatic chuck and control the cleanliness of the surface of the electrostatic chuck, thereby effectively improving the stability of the back pressure of the wafer, prolonging the service cycle of the electrostatic chuck, and reducing the production cost.

According to an embodiment of the present disclosure, referring to FIGS. 5 and 6, the wafer 4 is attracted to the electrostatic chuck 2 in the reaction chamber 1 by electrostatic force.

In this embodiment, the electrostatic chuck is to be cleaned and the pressure value is less than the preset range as an example for description. As shown in FIG. 2, the controlling method includes the following steps:

Step S200: obtaining a pressure value between the wafer and the electrostatic chuck.

The pressure value may be measured and recorded by a pressure gauge in the deposition device.

Step S210: when the pressure value is less than a preset range, the deposition device sending out an alarm signal to determine whether the working state of the electrostatic chuck meets use requirements.

When the working state of the electrostatic chuck meets the use requirements, step S220 is executed; when the working state of the electrostatic chuck does not meet the use requirements, step S230 is executed.

The preset range and the deposition device sending out an alarm signal may refer to the above embodiment, and details are not described herein again.

In this embodiment, the working state of the electrostatic chuck may be configured to characterize the use state of the electrostatic chuck. It should be noted that the working state of the electrostatic chuck may be represented by a ventilation state of the through holes, that is, a proportion of the through holes in a good ventilation state on the electrostatic chuck. When the proportion of the through holes in a good ventilation state is greater than a preset value, it is determined that the working state of the electrostatic chuck meets the use requirements.

As shown in FIG. 4, the working state of the electrostatic chuck 2 may be characterized by an electrostatic chuck hole map. When the through holes 21 on the electrostatic chuck 2 are not blocked, the electrostatic chuck hole map shows corresponding attraction protrusions, and a pattern in accordance with the arrangement of the through holes 21 on the electrostatic chuck 2 is formed on the attraction protrusions. During the processing of the wafer, as the production capacity increases, the through holes will be blocked by the oxide in the reaction chamber. As such, when the wafer is attracted to the electrostatic chuck, attraction protrusions will not be formed at the blocked through holes on the electrostatic chuck hole map. After the electrostatic chuck hole map is tested, the working state of the electrostatic chuck may be characterized according to the number of attraction protrusions on the electrostatic chuck hole map or the pattern formed, and then configured to determine the proportion of the through holes in a good ventilation state on the electrostatic chuck, so as to determine whether the working state of the electrostatic chuck meets the requirements.

For example, the preset value may be 40%. That is, when the proportion of the through holes in the electrostatic chuck that are in a good ventilation state is greater than 40%, it may be considered that the working state of the electrostatic chuck meets the use requirements. However, as the production capacity of wafers increases, most of the through holes on the electrostatic chuck may be blocked, which results in poor air permeability on the surface of the electrostatic chuck, reduces its conductivity, and then reduces the back pressure of the wafer to trigger the alarm. As such, the electrostatic chuck needs to be cleaned for subsequent wafer processing.

Step S220: when the working state of the electrostatic chuck meets the use requirements, executing a first cleaning operation and a second cleaning operation in sequence on the electrostatic chuck.

The first cleaning operation includes: when the reaction chamber is within a first preset pressure range, adjusting the distance between the electrostatic chuck and a preset position of the reaction chamber. The preset distance includes the bottom of the reaction chamber. The first preset pressure range may be a pressure range in the reaction chamber when the wafer is in a normal processing or normal attraction state.

In this embodiment, the impact stroke of a cleaning gas can be increased by reducing the distance between the electrostatic chuck and the bottom of the reaction chamber, so that the cleaning gas performs a first cleaning process on the electrostatic chuck to improve the cleanliness of the surface of the electrostatic chuck.

The second cleaning operation includes: adjusting the flow of the cleaning gas introduced into the reaction chamber. After the first cleaning operation on the electrostatic chuck is completed, a second cleaning process is performed on the electrostatic chuck by adjusting the flow of the cleaning gas. In this step, the flow of the cleaning gas introduced into the reaction chamber can be reduced to perform the second cleaning process on the electrostatic chuck, so as to further improve the cleanliness of the surface of the electrostatic chuck, that is, increase the proportion of the through holes in a good ventilation state.

In this embodiment, as shown in FIG. 4, when the proportion of the through holes in the electrostatic chuck 2 that are in a good ventilation state is within a first preset value interval, the first cleaning operation and the second cleaning operation may be performed in sequence. For example, when the first preset value interval ranges from 40% to 60%, the first cleaning operation and then the second cleaning operation may be performed on the electrostatic chuck.

The flow of the cleaning gas introduced into the reaction chamber during the second cleaning operation is less than that of the cleaning gas introduced into the reaction chamber during the first cleaning operation.

It should be noted that the electrostatic chuck after the second cleaning operation may trigger a device alarm during wafer processing, or the back pressure of the wafer is still not restored to normal during use, then the electrostatic chuck needs to be replaced.

Step S230: when the working state of the electrostatic chuck does not meet the use requirements, performing a troubleshooting operation on the electrostatic chuck.

In this step, when the working state of the electrostatic chuck does not meet the use requirements, the reaction chamber needs to be opened for corresponding troubleshooting on the electrostatic chuck or the electrostatic chuck.

After the first cleaning operation and the second cleaning operation are performed on the electrostatic chuck, the proportion of the through holes in a good aeration state is effectively increased, the stability of the back pressure of the wafer is ensured, the problem of abnormal alarm for the back pressure of the wafer is solved, the downtime of troubleshooting is reduced, and the smooth production of wafer products is ensured to effectively increase production capacity.

According to an embodiment of the present disclosure, the electrostatic chuck is to be cleaned and the pressure value is less than the preset range as an example for description. As shown in FIG. 3, the controlling method may further include the following steps:

Step S300: obtaining a pressure value between the wafer and the electrostatic chuck.

The pressure value may be measured and recorded by a pressure gauge in the deposition device.

Step S310: when the pressure value is less than a preset range, the deposition device sending out an alarm signal, and determine whether the working state of the electrostatic chuck meets use requirements.

When the working state of the electrostatic chuck meets the use requirements, step S320 is executed; when the working state of the electrostatic chuck does not meet the use requirements, step S330 is executed.

Step S320: when the working state of the electrostatic chuck meets the use requirements, executing a first cleaning operation and/or a second cleaning operation on the electrostatic chuck.

The first cleaning operation includes: when the reaction chamber is within a first preset pressure range, the distance between the electrostatic chuck and a preset position of the reaction chamber is adjusted, and the flow of a cleaning gas introduced into the reaction chamber flow is also adjusted. The preset distance includes the bottom of the reaction chamber. The first preset pressure range may be a pressure range in the reaction chamber when the wafer is in a normal processing or normal attraction state.

In this embodiment, the impact stroke of the cleaning gas can be controlled and increased by reducing the distance between the electrostatic chuck and the bottom of the reaction chamber and reducing the flow of the cleaning gas introduced into the reaction chamber, so that the cleaning gas performs a first cleaning process on the electrostatic chuck to improve the cleanliness of the surface of the electrostatic chuck.

The second cleaning operation includes: adjusting the flow of the cleaning gas introduced into the reaction chamber. After the first cleaning operation on the electrostatic chuck is completed, a second cleaning process is performed on the electrostatic chuck by adjusting the flow of the cleaning gas. In this step, the flow of the cleaning gas introduced into the reaction chamber can be reduced to perform the second cleaning process on the electrostatic chuck, so as to further improve the cleanliness of the surface of the electrostatic chuck, that is, increase the proportion of the through holes in a good ventilation state.

The flow of the cleaning gas introduced into the reaction chamber during the second cleaning operation is less than that of the cleaning gas introduced into the reaction chamber during the first cleaning operation.

In this embodiment, when the proportion of the through holes in the electrostatic chuck that are in a good ventilation state is within a first preset value interval, the first cleaning operation and the second cleaning operation may be performed in sequence. For example, when the first preset value interval ranges from 40% to 60%, the first cleaning operation and then the second cleaning operation may be performed on the electrostatic chuck. When the proportion of the through holes in the electrostatic chuck that are in a good ventilation state is within a second preset value interval, only the second cleaning operation is performed on the electrostatic chuck. For example, when the second preset value interval ranges from 60% to 70%, only the second cleaning operation is performed on the electrostatic chuck. After the first cleaning operation and the second cleaning operation, foreign matters may be effectively removed from the surface of the electrostatic chuck, and ensure the cleanliness of the surface. It should be noted that the cleaning effects of the electrostatic chuck after the first cleaning operation and the second cleaning operation may also be characterized by electrostatic chuck hole maps, as shown in FIG. 4. In FIG. 4, the three maps in the same column from top to bottom respectively represent: an effect map of the electrostatic chuck before the first cleaning operation, an effect map after the first cleaning operation, and an effect map after the second cleaning operation. It should be noted that the effect maps shown in the two columns are effect maps verified by two cleaning operations.

The electrostatic chuck after the second cleaning operation is tested to obtain the final working state of the electrostatic chuck. The test effect of the electrostatic chuck may be characterized by the electrostatic chuck hole map. When the final working state of the electrostatic chuck does not meet the use requirements, the electrostatic chuck is replaced. The final working state of the electrostatic chuck may include triggering a device alarm during wafer processing; or when the back pressure of the wafer is still not restored to normal during use, the electrostatic chuck is replaced.

Step S330: when the working state of the electrostatic chuck does not meet the use requirements, performing a troubleshooting operation on the electrostatic chuck.

This step is the same as the implementation of step S230 described above, and details are not described herein again.

In a disclosed embodiment, after the pressure value between the wafer and the electrostatic chuck is obtained, when the pressure value is less than the preset range, after the step of the deposition device sending out alarm information, before the step of obtaining a use state of the electrostatic chuck, a preliminary cleaning operation may also be performed on the electrostatic chuck first. That is, a cleaning condition is set when an A target is used in the reaction chamber of the deposition device, for example, a process position of the electrostatic chuck and a process pressure in the reaction chamber are set when the A target is used, and the cleaning operation performed for the cleaning condition of the A target is the preliminary cleaning operation. When the A target is replaced by a B target, the cleaning condition of the A target may be suitable for the B target, or may not be suitable for the B target. As such, the B target may be first cleaned by the preliminary cleaning operation performed for the A target, and if the cleaning effect does not meet the use requirements of the electrostatic chuck, steps S100 to S110, steps S200 to S230, or steps S300 to S330 in the above embodiment are executed. The electrostatic chuck in the B target or the electrostatic chuck is cleaned.

According to an embodiment of the present disclosure, as shown in FIGS. 4 to 7, a high-temperature deposition device is taken as an example to describe the method for controlling the deposition device.

As shown in FIGS. 4 and 5, an electrostatic chuck 2 and a vacuum pump 3 are arranged in the reaction chamber 1, and the wafer 4 is attracted to the electrostatic chuck 2 by electrostatic attraction. The vacuum pump 3 is connected to the reaction chamber 1 and communicated with the inside of the reaction chamber 1, and remove process by-products and promote the maintenance of a predetermined pressure in the reaction chamber 1. A target 5 containing aluminum is disclosed on the top of the reaction chamber 1.

When a physical deposition process is performed in the reaction chamber 1, an alternating current (AC) is used as a power source for radio frequency sputtering as an example. An etching gas, such as argon (Ar), is introduced into the reaction chamber 1, the etching gas Ar absorbs radio frequency (RF) energy to dissociate out negative electrons, the argon Ar reacts with the negative electrons to form Ar⁺, and the Ar⁺ is attracted by a radio frequency bias and accelerates the bombardment to the surface of the electrostatic chuck 2. As shown in FIG. 5, the arrow above the wafer 4 indicates the moving direction of Ark, and the arrow below the wafer indicates the back pressure of the wafer 4.

In this embodiment, the reaction chamber is a high-temperature chamber, which may cause easy formation of an oxide in the reaction chamber and adhesion of the oxide to the surface of the electrostatic chuck during heating. As the production capacity increases, substances that may exist on the back of the wafer fall onto the surface of the electrostatic chuck due to high-temperature baking, so that the through holes on the surface of the electrostatic chuck are blocked to reduce its conductivity, then uneven air flow on the back of the wafer and reduction of the electrostatic attraction capacity are caused, and eventually the deposition device triggers a pressure alarm on the back of the wafer.

When the deposition device triggers the pressure alarm on the back of the wafer, the original cleaning process (preliminary cleaning operation) of the deposition device is executed to preliminarily clean the electrostatic chuck. In the originally designed cleaning process, the electrostatic chuck is located at a first position L1 in the reaction chamber, and the process pressure in the reaction chamber is a first pressure.

However, when products such as wafers undergo different processes and use different aluminum targets, the etching rate of the etching gas changes, and the original cleaning process of the deposition device cannot improve the status of abnormal pressure on the back of the wafer.

At this time, the pressure value between the wafer and the electrostatic chuck is measured. When the measured pressure value is less than the preset range, the working state of the electrostatic chuck is tested, and when the working state of the electrostatic chuck meets the use requirements, the cleaning operation is executed.

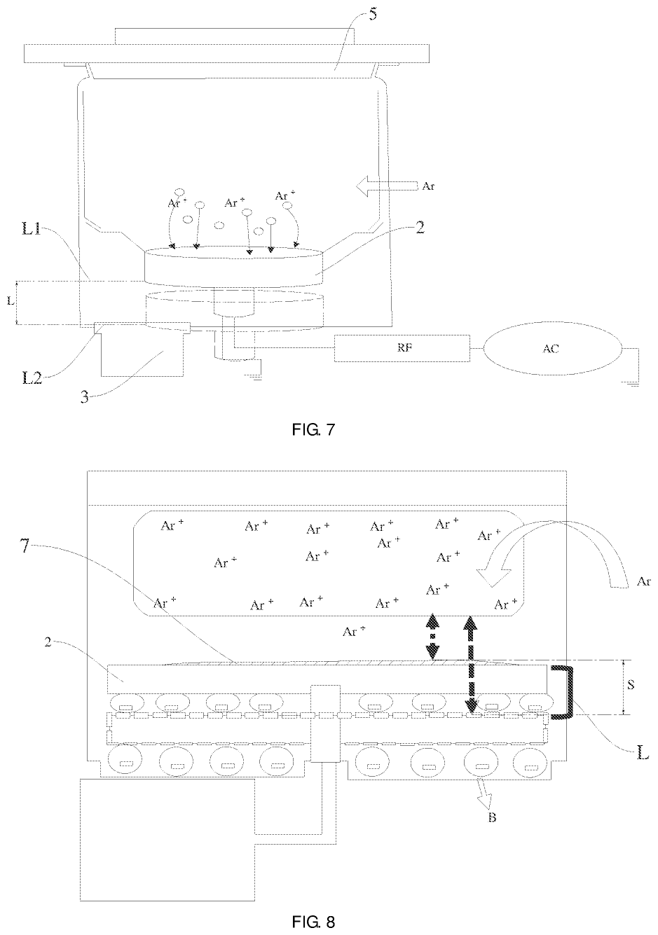

As described in FIGS. 7 and 8, first, the first cleaning operation is executed on the electrostatic chuck. That is, the electrostatic chuck at the first position L1 in the reaction chamber is moved to a second position L2, wherein the second position L2 is close to the bottom of the reaction chamber, and the distance between the first position L1 and the second position L2 is L. As such, the average free radical distance S of Ar⁺ is increased, the energy of Ar⁺ bombarding the surface of the electrostatic chuck 2 is increased, and the etching rate of the oxide 7 on the surface of the electrostatic chuck 2 is increased, and effectively clean the electrostatic chuck and improve the cleanliness of the surface, so that the back pressure of the wafer is stable. The arrow B in FIG. 8 indicates that the negative bias formed by the radio frequency (RF) attracts the positively charged Ar⁺ to bombard the surface of the electrostatic chuck for etching.

Second, the second cleaning operation is executed on the electrostatic chuck after the first cleaning operation is executed. The flow of the cleaning gas introduced into the reaction chamber is reduced, that is, the process pressure in the reaction chamber is controlled by controlling the flow of the etching gas Ar, so that the first pressure in the reaction chamber drops to a second pressure. The pressure drop means that the Ar introduced into the reaction chamber is reduced, the formed Ar⁺ is reduced, and the total energy for bombarding the surface of the electrostatic chuck is reduced, which is suitable for finishing cleaning of the electrostatic chuck to achieve a good cleaning effect on the electrostatic chuck.

In the embodiment of the present disclosure, the first cleaning operation is executed on the electrostatic chuck first, then the second cleaning operation is executed, and the etching rate is controlled by the process position and process pressure, to solve the problem of abnormal alarm for the back pressure of the wafer, thereby effectively ensuring that the back pressure of the wafer is in a stable state, reducing the downtime of processing, and ensuring smooth production of products to increase production capacity.

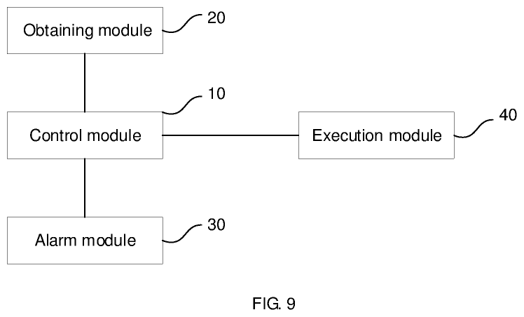

As shown in FIG. 9, an embodiment of the present disclosure further provides a system for controlling a deposition device, applied to the deposition device, the deposition device including a reaction chamber and an electrostatic chuck arranged in the reaction chamber, and the electrostatic chuck carrying a wafer. The controlling system includes an obtaining module 20, a control module 10, an alarm module 30 and an execution module 40, wherein the control module 10 is connected to the obtaining module 20, the alarm module 30 and the execution module 40 respectively.

The obtaining module 20 is configured to obtain a pressure value between the wafer 4 and the electrostatic chuck 2.

The control module 10 is configured to receive the pressure value, determine whether the pressure value exceeds a preset range, obtain a use state of the electrostatic chuck 2, and generate an operation instruction according to the determination result and the use state of the electrostatic chuck 2.

The alarm module 30 is configured to be controlled by the control module 10 to send out an alarm signal when the pressure value exceeds the preset range.

The execution module 40 is configured to receive the operation instruction, and execute a cleaning operation according to the operation instruction.

According to an embodiment of the present disclosure, the control module 10 is configured to:

determine whether the working state of the electrostatic chuck 2 meets use requirements, and generate the operation instruction if the working state of the electrostatic chuck 2 meets the use requirements, wherein the working state of the electrostatic chuck 2 is configured to characterize the use state of the electrostatic chuck 2; or generate an operation instruction for troubleshooting the electrostatic chuck 2 if the working state of the electrostatic chuck 2 does not meet the use requirements.

The execution module 40 is configured to: execute a first cleaning operation on the electrostatic chuck 2 according to the operation instruction, the first cleaning operation including, when the reaction chamber 1 is within a first preset pressure range, adjusting the distance between the electrostatic chuck 2 and a preset position of the reaction chamber 1, or adjusting the distance between the electrostatic chuck 2 and the preset position of the reaction chamber 1 and adjusting the flow of a cleaning gas introduced into the reaction chamber 1; and execute a second cleaning operation on the electrostatic chuck 2 after the first cleaning operation, the second cleaning operation including adjusting the flow of the cleaning gas introduced into the reaction chamber 1

Further, the execution module 40 is specifically configured to: when the pressure value is less than the preset range, reduce the distance between the electrostatic chuck 2 and the preset position of the reaction chamber 1, or reduce the distance between the electrostatic chuck 2 and the preset position of the reaction chamber 1 and reduce the flow of the cleaning gas introduced into the reaction chamber 1, wherein the preset position includes the bottom of the reaction chamber 1;

and execute the second cleaning operation of reducing the flow of the cleaning gas introduced into the reaction chamber 1 on the electrostatic chuck 2 after the first cleaning operation.

The control module 10 is further configured to: obtain a final working state of the electrostatic chuck 2 after the second cleaning operation; and issue an instruction of replacing the electrostatic chuck 2 if the final working state of the electrostatic chuck 2 does not meet the use requirements.

The control module 10 is further configured to: control the execution module 40 to perform a preliminary cleaning operation on the electrostatic chuck 2.

The method and system for controlling the deposition device according to the embodiments of the present disclosure can be applied to a process of removing foreign matters by physical bombardment in a small reaction chamber, and the first cleaning operation and then the second cleaning operation are performed on the electrostatic chuck in the reaction chamber to improve the cleanliness of the surface of the electrostatic chuck, thereby effectively improving the cleanliness of the electrostatic chuck, then solving the problem of abnormal alarm for the back pressure of the wafer, reducing the downtime of troubleshooting, and ensuring smooth production of products to improve production capacity.

The embodiments or implementations in this specification are described in a progressive manner, each embodiment focuses on the differences from other embodiments, and the same or similar parts between the various embodiments may be referred to each other.

In the description of this specification, the descriptions with reference to the terms “embodiment”, “exemplary embodiment”, “some implementations”, “schematic implementation”, “example”, etc. mean that specific features, structures, materials or characteristics described in conjunction with the embodiments or examples are included in at least one embodiment or example of the present application.

In this specification, the schematic descriptions of the above terms do not necessarily refer to the same embodiment or example. Moreover, the described specific features, structures, materials or characteristics may be combined in an appropriate manner in any one or more embodiments or examples.

In the description of the present disclosure, it should be noted that the orientations or positional relationships indicated by the terms “center”, “upper”, “lower”, “left”, “right”, “vertical”, “horizontal”, “inner”, “outer”, etc. are based on the orientations or positional relationships shown in the accompanying drawings, and are intended to facilitate the description of the present disclosure and simplify the description only, rather than indicating or implying that the device or element referred to must have a particular orientation or be constructed and operated in a particular orientation, and will not to be interpreted as limiting the present disclosure.

It may be understood that the terms “first”, “second”, etc. used in the present disclosure may be used in the present disclosure to describe various structures, but these structures are not limited by these terms. These terms are only configured to distinguish the first structure from another structure. In one or more drawings, the same elements are represented by similar reference numerals. For the sake of clarity, various parts in the drawings are not drawn to scale. In addition, some well-known parts may not be shown. For the sake of brevity, the structure obtained after several steps may be described in one figure. Many specific details of the present disclosure are described below, such as the structure, material, dimension, treatment process and technology of devices, in order to understand the present disclosure more clearly. However, as those skilled in the art can understand, the present disclosure may not be implemented according to these specific details.

Finally, it should be noted that the above embodiments are merely configured to describe, but not to limit, the technical solutions of the present disclosure. Although the present disclosure is described in detail with reference to the above embodiments, those of ordinary skill in the art should understand that various modifications may be made to the technical solutions described in the foregoing embodiments, or equivalent substitutions may be made to some or all technical features thereof, and these modifications or substitutions do not make the essences of the corresponding technical solutions depart from the scope of the technical solutions of the embodiments of the present disclosure.

### INDUSTRIAL APPLICABILITY

The method for controlling a deposition device provided by the embodiments of the present disclosure can perform a corresponding cleaning operation according to the use state of the electrostatic chuck when the back pressure of the wafer is abnormally alarmed, thereby effectively solving the problem of abnormal alarm for the back pressure of the wafer, reducing the downtime of troubleshooting, ensuring the smooth progress of products, and increasing the production capacity of the device.

1. A method for controlling a deposition device, applied to the deposition device, the deposition device comprising a reaction chamber and an electrostatic chuck arranged in the reaction chamber, the electrostatic chuck carrying a wafer, the method for controlling the deposition device comprising:
obtaining a pressure value between the wafer and the electrostatic chuck; and
when the pressure value exceeds a preset range, the deposition device sending out an alarm signal, and executing a cleaning operation according to a use state of the electrostatic chuck.

2. The method for controlling the deposition device according to claim 1, the executing the cleaning operation according to the use state of the electrostatic chuck comprising:
determining whether a working state of the electrostatic chuck meets use requirements, wherein the working state is used to characterize the use state of the electrostatic chuck; and
if the working state of the electrostatic chuck meets the use requirements, executing the cleaning operation.

3. The method for controlling the deposition device according to claim 2, the executing the cleaning operation comprising:
executing a first cleaning operation on the electrostatic chuck, the first cleaning operation comprising:
when the reaction chamber is within a first preset pressure range, adjusting a distance between the electrostatic chuck and a preset position of the reaction chamber, or adjusting the distance between the electrostatic chuck and the preset position of the reaction chamber and adjusting a flow of a cleaning gas introduced into the reaction chamber; and
executing a second cleaning operation on the electrostatic chuck, the second cleaning operation comprising adjusting the flow of the cleaning gas introduced into the reaction chamber.

4. The method for controlling the deposition device according to claim 3, the executing the first cleaning operation on the electrostatic chuck comprising:
when the pressure value is less than the preset range, reducing the distance between the electrostatic chuck and the preset position of the reaction chamber, or reducing the distance between the electrostatic chuck and the preset position of the reaction chamber and reducing the flow of the cleaning gas introduced into the reaction chamber, wherein the preset position comprises a bottom of the reaction chamber.

5. The method for controlling the deposition device according to claim 4, the executing the second cleaning operation on the electrostatic chuck comprising:
when the pressure value is less than the preset range, reducing the flow of the cleaning gas introduced into the reaction chamber;
wherein, the flow of the cleaning gas introduced into the reaction chamber during the second cleaning operation is less than the flow of the cleaning gas introduced into the reaction chamber during the first cleaning operation.

6. The method for controlling the deposition device according to claim 5, further comprising: obtaining a final working state of the electrostatic chuck after the second cleaning operation; and
replacing the electrostatic chuck if the final working state of the electrostatic chuck does not meet the use requirements.

7. The method for controlling the deposition device according to claim 2, the determining whether the working state of the electrostatic chuck meets use requirements further comprising:
if the working state of the electrostatic chuck does not meet the use requirements, performing a troubleshooting operation on the electrostatic chuck.

8. The method for controlling the deposition device according to claim 1, the deposition device sending out the alarm signal, and before the step of executing the cleaning operation according to the use state of the electrostatic chuck, the method for controlling the deposition device further comprising:
executing a preliminary cleaning operation on the electrostatic chuck.

9. A system for controlling a deposition device, applied to the deposition device, the deposition device comprising a reaction chamber and an electrostatic chuck arranged in the reaction chamber, the electrostatic chuck carrying a wafer, the system for controlling the deposition device comprising an obtaining module, a control module, an alarm module and an execution module, wherein the control module is connected to the obtaining module, the alarm module, and the execution module respectively;
the obtaining module is configured to obtain a pressure value between the wafer and the electrostatic chuck;
the control module is configured to receive the pressure value, determine whether the pressure value exceeds a preset range, obtain a use state of the electrostatic chuck, and generate an operation instruction according to a determination result and a use state of the electrostatic chuck;
the alarm module is configured to be controlled by the control module to send out an alarm signal when the pressure value exceeds the preset range;
the execution module is configured to receive the operation instruction, and execute a cleaning operation according to the operation instruction.

10. The system for controlling the deposition device according to claim 9, the control module is further configured to:
determine whether a working state of the electrostatic chuck meets use requirements, and generate the operation instruction if the working state of the electrostatic chuck meets the use requirements, wherein the working state of the electrostatic chuck is configured to characterize the use state of the electrostatic chuck.

11. The system for controlling the deposition device according to claim 10, the execution module being further configured to:
execute a first cleaning operation on the electrostatic chuck according to the operation instruction, the first cleaning operation comprising, when the reaction chamber is within a first preset pressure range, adjusting a distance between the electrostatic chuck and a preset position of the reaction chamber, or adjusting the distance between the electrostatic chuck and the preset position of the reaction chamber and adjusting a flow of a cleaning gas introduced into the reaction chamber; and
execute a second cleaning operation on the electrostatic chuck after the first cleaning operation, the second cleaning operation comprising adjusting the flow of the cleaning gas introduced into the reaction chamber.

12. The system for controlling the deposition device according to claim 11, the execution module being further configured to:
when the pressure value is less than the preset range, reduce the distance between the electrostatic chuck and the preset position of the reaction chamber, or reduce the distance between the electrostatic chuck and the preset position of the reaction chamber and reduce the flow of the cleaning gas introduced into the reaction chamber, wherein the preset position comprises a bottom of the reaction chamber.

13. The system for controlling the deposition device according to claim 12, the execution module being further configured to:
execute the second cleaning operation of reducing the flow of the cleaning gas introduced into the reaction chamber on the electrostatic chuck after the first cleaning operation;
wherein, the flow of the cleaning gas introduced into the reaction chamber during the second cleaning operation is less than the flow of the cleaning gas introduced into the reaction chamber during the first cleaning operation.

14. The system for controlling the deposition device according to claim 13, the control module being further configured to:
obtain a final working state of the electrostatic chuck after the second cleaning operation; and
issue an instruction of replacing the electrostatic chuck if the final working state of the electrostatic chuck does not meet the use requirements.

15. The system for controlling the deposition device according to claim 10, the control module being further configured to: if the working state of the electrostatic chuck does not meet the use requirements, generate an operation instruction of troubleshooting the electrostatic chuck.

16. The system for controlling the deposition device according to claim 9, the control module being further configured to: control the execution module to perform a preliminary cleaning operation on the electrostatic chuck.
